(19) United States
(12) Patent Application Publication
(10) Pub. No.: US 2025/0059641 A1
(43) Pub. Date: Feb. 20, 2025

(54) INLINE SYSTEM FOR COATING INDIVIDUAL SUBSTRATES OR GROUPS OF SUBSTRATES AND METHOD FOR COATING INDIVIDUAL SUBSTRATES OR SUBSTRATE GROUPS IN AN INLINE COATING SYSTEM

(71) Applicant: Rainer Cremer, Monschau (DE)

(72) Inventor: Rainer Cremer, Monschau (DE)

(21) Appl. No.: 18/721,975

(22) PCT Filed: Oct. 24, 2022
(86) PCT No.: PCT/DE2022/100778

§ 371 Date: Jun. 20, 2024

(30) Foreign Application Priority Data
Dec. 22, 2021 (DE) 10 2021 134 254.6

(51) Int. Cl. C23C 14/56

(52) U.S. Cl. CPC C23C 14/568; C23C 14/566

(57) ABSTRACT

The invention relates to an inline system for coating individual substrates or groups of substrates, which has several chambers arranged one behind the other and evacuatable via pumps, namely a feed chamber, a waiting chamber, at least one process chamber, a further waiting chamber and a discharge chamber, through which the substrates or substrate groups pass in succession and which can each be closed by valves. According to the invention, the feed chamber and the discharge chamber each have a capacity for simultaneously receiving several, namely n, substrates or substrate groups, as well as a waiting chamber the capacity of which allows (n−1) substrates or substrate groups to be received, whereas the receiving capacity of the treatment chambers is limited to one substrate or one substrate group in each case.

### TECHNICAL FIELD

The invention relates to an inline system for coating individual substrates or groups of substrates, which has several chambers arranged one behind the other and evacuatable via pumps, namely a feed chamber, a waiting chamber, at least one process chamber, a further waiting chamber and a discharge chamber, through which the substrates or substrate groups pass in succession and which can each be closed by valves.

The invention further relates to a method for coating individual substrates or substrate groups in such an inline coating system.

### DISCUSSION OF ART

Workpiece coatings are used, for example, to increase the wear resistance and service life of components. In many cases, tool coatings also serve as corrosion protection or to improve physical properties. The processes mentioned here are chemical vapor deposition (CVD) or physical vapor deposition (PVD), which has the advantage of a significantly lower deposition temperature compared to CVD. In addition to batch processes in so-called batch systems, in which a large number of workpieces are arranged in a fixed position in a coating vessel during the coating process, coatings are also applied in a continuous process in which the substrates pass through various stations one after the other in continuous systems. These stations are realized by different chambers of an inline system, in which the vacuum required for the CVD or PVD processes is generated, the workpiece surfaces are etched and coated, possibly by two layers that are applied one after the other. In the case of very thin layers, such as optical coatings or coatings for batteries and fuel cells, the evacuation and ventilation time becomes the speed-determining step that defines the productivity of the system. For example, surface etching and coating each require approx. 1 min, whereas loading and unloading can be carried out in less than 1 min per robot. Due to technical limitations, no feeding or discharging process can take place in such short times. The technically feasible limit for these processes appears to be around 2 minutes.

### BRIEF DESCRIPTION

In an embodiment, the invention relates to an inline system for coating individual substrates or groups of substrates, which has several chambers arranged one behind the other and evacuatable via pumps, namely a feed chamber, a waiting chamber, at least one process chamber, a further waiting chamber and a discharge chamber, through which the substrates or substrate groups pass in succession and which can each be closed by valves. According to the invention, the feed chamber and the discharge chamber each have a capacity for simultaneously receiving several, namely n, substrates or substrate groups, as well as a waiting chamber the capacity of which allows (n−1) substrates or substrate groups to be received, whereas the receiving capacity of the treatment chambers is limited to one substrate or one substrate group in each case.

### BRIEF DESCRIPTION OF THE FIGURES

The present invention will be better understood from reading the following description of non-limiting embodiments, with reference to the attached drawings, wherein below:

FIG. 1, an illustration of a system that includes five chambers known from the prior art is shown;

FIG. 2 depicts an inline system for coating substrates according to an embodiment of the invention;

FIG. 3 shows an alternative embodiment of an inline system for coating substrates;

FIG. 4 depicts an additional alternative embodiment of an inline system for coating substrates.

### DETAILED DESCRIPTION

Reference will be made below in detail to exemplary embodiments of the invention, examples of which are illustrated in the accompanying drawings. Wherever possible, the same reference characters used throughout the drawings refer to the same or like parts.

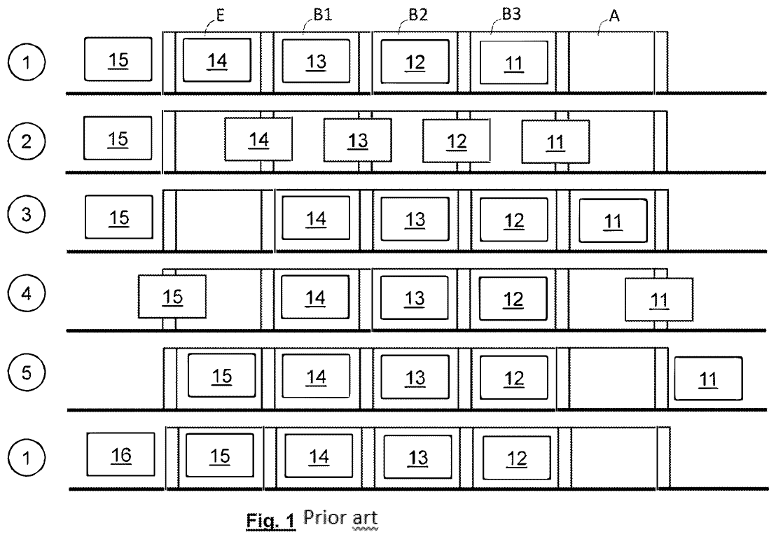

In FIG. 1, a sketch of a system that includes five chambers known from the prior art is shown which features fa loading area, a feed chamber, an etching chamber, two successive coating chambers, a discharge chamber and an unloading area. The chambers mentioned are each provided with pumps and connected to valves so that they can be ventilated and deaerated as required and independently of each other.

In FIG. 1, a sketch of five different loading states is shown, which are designated by line numbers 1, 2, 3, 4 and 5. The workpieces bear the reference numbers 11, 12, 13, 14 and 15. The coating chambers are configured in such a way that one of the workpieces 11 to 15 each can be received. The workpiece 15 is located in the so-called loading area, whereas the workpiece 14 is temporarily stored in the feed chamber until the required vacuum pressure is reached. At the same time, the workpiece 13 is etched in an etching chamber and the workpiece 12 is provided with a first coating in a first coating chamber and the workpiece 11 is provided with a second coating (as an outer layer on the first coating) in a second coating chamber.

Specifically, the evacuation and ventilation times of the system are 2 minutes each. In the second step (second line), the workpieces 11, 12, 13 and 14 are each pushed into the next chamber after opening the corresponding valves, namely the workpiece 14 into the etching chamber, the workpiece 13 into the first coating chamber, the workpiece 12 into the second coating chamber and the workpiece 11 into the discharge chamber. The end of this transfer is shown in the third line. The feed chamber is then opened for introducing the workpiece 15. and at the same time the workpiece 11 is removed from the discharge chamber after ventilation, which is shown in the fourth line.

As soon as the workpiece 15 is positioned in the feed chamber and the workpiece 11 is transported from the discharge chamber to the unloading area, the valves of the feed chamber and the discharge chamber are closed again, after which the feed chamber is evacuated. At the same time, the surface etching of the first coating and the second coating of the respective workpieces, which are located in the respective chambers, is completed. In the last line, which is also provided with the “number 1”, the provision of a further workpiece 16 is indicated.

The throughput process described above has a cycle time that is specified by the evacuation time of 2 minutes.

It is the task of the present invention to improve an inline system of the type mentioned above or a method of the type mentioned above in such a way that higher productivity is achieved.

This task is solved by an inline system according to claim 1 or by a method according to claim 5.

According to the invention, the feed chamber and the discharge chamber are each enlarged so that they have a throughput length for simultaneously receiving n substrates or substrate groups arranged one behind the other or side by side, where n is a natural number. The waiting chamber arranged between the feed chamber and the process chamber as well as between the discharge chamber and the process chamber has a capacity for receiving (n−1) substrates or substrate groups, whereas the capacity of the treatment chambers is limited to receiving one substrate each. The feed and discharge chambers are preferably n times as long as the treatment chambers, namely the chambers of equal length for etching and coating, while the waiting chambers are n−1 times as long as the treatment chambers. This ensures that the vacuum required for the process is created simultaneously for n substrates or substrate groups in the deaeration chamber. The most time-consuming process of deaeration and ventilation is thus “distributed” over n substrates or n substrate groups, so that the most time-consuming steps of the two outer chambers (for ventilation and deaeration) only have to be carried out in every nth cycle and the cycle time of the other chambers, which is considerably shorter, can be maintained. Although the enlargement of the two outer chambers (namely the feed and discharge chambers) and the insertion of respective waiting chambers leads to an increase in system costs, this is offset by the n-fold increase in the productivity of the system. In any case, the additional system costs are significantly lower than the installation of several production lines to enable the same cycle ratios.

Preferably, the inline system possesses an etching chamber as the first process chamber and at least one coating chamber, preferably two coating chambers for the deposition of successive layers. According to a further embodiment of the invention, the coating chambers have a PVD device.

In terms of process technology, the task is solved in that between respective etching and/or coating treatments, the substrates or substrate groups are moved in a composite from the feed chamber via the waiting chamber into the treatment chamber and a further waiting chamber into the discharge chamber and are treated in such a way that in successive steps the feed chamber is occupied with n substrates or n substrate groups and each of the treatment chambers is occupied with only one substrate or one substrate group in each case and the waiting chambers are free of substrates or substrate groups. In a next step, which follows, the substrates or substrate groups are moved forward in the compound so that, after completion of this step, a substrate or a substrate group discharged from each treatment chamber is replaced by a substrate or a substrate group carried forward and that, after partial occupancy of the waiting chamber, occupancy of the feed chamber with n substrates or substrate groups is carried out, after which the sequence of substrate movement and chamber occupancy described above is repeated successively.

The core idea of the present invention is that the maximum occupancy rate of the feed and discharge chambers is greater by the integer factor n in each case.

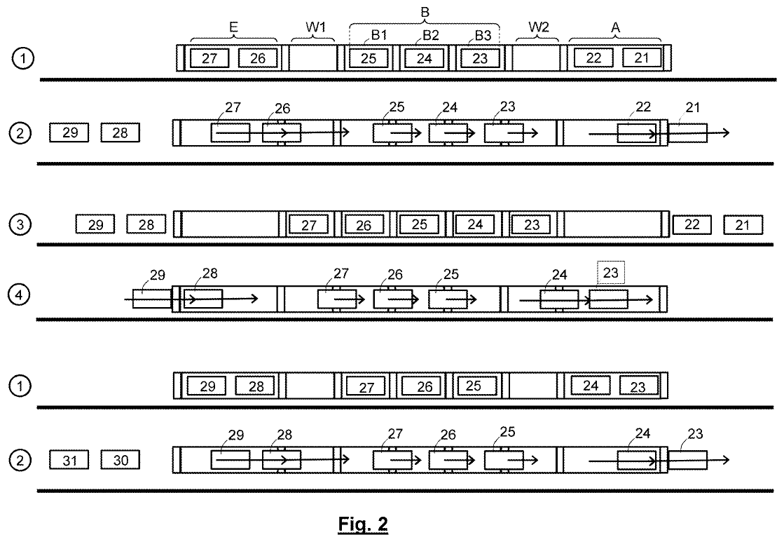

Examples of embodiments of the invention are shown in FIG. 2 to FIG. 4.

In FIG. 2, line 1, it can be seen that the feed chamber E and the discharge chamber A are approximately twice as long as the other chambers, namely the two waiting chambers W₁, W₂ and the centrally arranged treatment chambers B, in this case the etching chamber B₁, coating chamber B₂ and coating chamber B₃. Substrates 21, 22 and 26, 27 are arranged in the feed chamber and the discharge chamber, while substrates 23, 24, 25 are located in the etching chamber, the first coating chamber and the second coating chamber at the same time. The waiting chambers are empty. The valves between the individual chambers are closed, so that the feed chamber can be evacuated to the low pressure required for the PVD treatment. The discharge chamber is already ventilated while the feed chamber is being evacuated. At the same time, the substrate 25 is treated in the etching chamber B₁ and the substrates 23, 24 are coated in the coating chambers B₂, B₃. After completion of the time defined by the pump treatment, the valves between the feed chamber E and the first waiting chamber W₁ as well as from the waiting chamber W₁ to the etching chamber B₁ and from there to the coating chambers B₂, B₃ up to the second waiting chamber W₂ are each opened. By opening the last valve in the discharge chamber A, it can be ventilated. The substrates 21, 22, 23, 24, 25, 26, 27 are each pushed two chambers further into the neighboring chamber (to the right in line 2 in the illustration) until the occupancy rate shown in the third line is reached, in which the feed chamber E and the discharge chamber A are completely empty and there is one substrate each in the etching chamber B₁ and the two coating chambers B2, B3. The substrates 23, 27 are arranged in the waiting chambers; the two finished substrates 21, 22 have been discharged at the same time.

Line 4 shows how the feed chamber E is loaded with two substrates 28, 29 and at the same time the substrate 27 is fed into the etching chamber B₁ and the substrates 25, 26 are fed into the chambers B₂, B₃ for the first and second coating respectively. The substrate 23 previously arranged in the second waiting chamber W₂ is simultaneously transferred to the discharge chamber A, so that the initial situation is finally restored, in which two substrates 28, 29 are arranged in the feed chamber E and one substrate 25, 26, 27 in each of the treatment chambers B₁ to B₃ and two substrates 23, 24 in the discharge chamber A as well. The process now starts again. The valves shown in each case, which are designed as sliding valves, for example, are only opened when a substrate is to be conveyed from one chamber to the next. The end valves of the feed chamber E and the discharge chamber A are only opened for ventilation. FIG. 2 shows that two substrates or substrate groups are fed successively into the feed chamber E and two substrates are removed from the discharge chamber A in the same way. The double occupancy of the feed chamber E and the discharge chamber A results in a reduced evacuation and ventilation time per substrate, which increases the overall product rate.

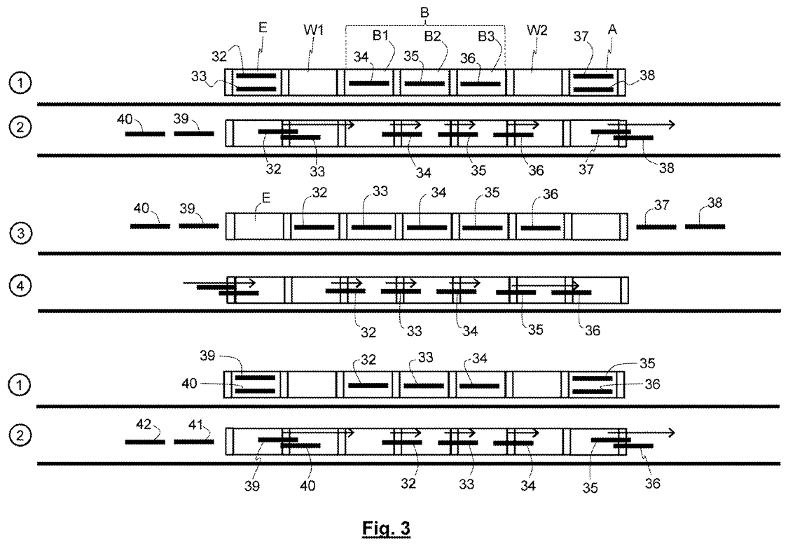

FIG. 3 shows a sketched alternative embodiment of an inline system for simultaneously receiving two substrates 32, 33 arranged next to each other in the feed chamber E and 37, 38 in the discharge chamber A. At the start of the process shown in line 1, individual substrates 34 are located in the etching chamber B₁, 35 in the coating chamber B₂and 36 in the coating chamber B₃. In contrast to FIG. 2, a top view of the system has been chosen to illustrate the side-by-side arrangement. At the start of the process shown in line 1, the feed chamber E is evacuated and the discharge chamber A is ventilated.

In the next step, shown in the second line, all the substrates 32 to 36 are transferred to the adjacent chamber and new substrates 39, 40 are provided in the loading area at the same time. The final state after this transfer can be seen in the third line, in which the ventilation of the feed chamber E is carried out at the same time. At this point, the substrate 32 is located in the waiting chamber W₁, wherein the valve between the feed chamber and the waiting chamber is closed, as is the valve between the waiting chamber and the etching chamber B₁, in which the substrate 33 is located. The substrates 34 and 35 are coated in the chambers B₁ and B₂. During this time, the substrate 36 remains in the waiting chamber W₂, while the substrates 37 and 38, which have already been treated, are already discharged. The discharge chamber A is evacuated after discharge. All ventilation and evacuation processes take approx. 1 min.

After the substrates 33, 34, 35 have been etched and coated, they are moved on to the next adjacent chamber, as can be seen in the fourth line, so that after this process is complete, the substrates 39, 40 are arranged in the feed chamber, the waiting chamber W₁ is empty and the substrates 32, 33, 34 are treated simultaneously in adjacent chambers B₁, B₂and B₃. At this time, the waiting chambers W₁ and W₂ are empty. All valves, with the exception of the end valve of the discharge chamber, are closed. The discharge chamber, in which again two adjacent substrates 35, 36 are present, is ventilated, after which the next process is started according to the presentation of the last line. In this chamber arrangement, the feed chamber and the discharge chamber are each designed as magazines.

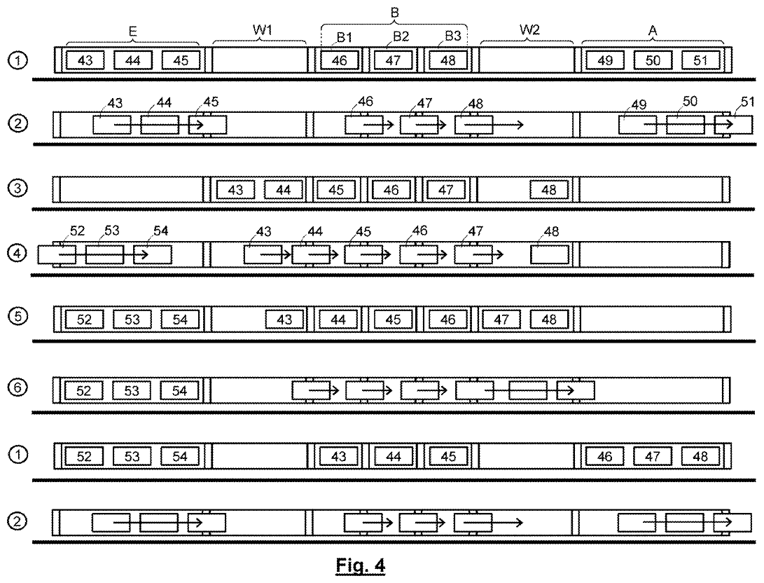

A further process and inline system variant is shown in FIG. 4. In this embodiment example, the feed chamber and the discharge chamber are dimensioned in such a way that these chambers can each receive three substrates simultaneously. In the example shown, the substrates are arranged one behind the other, but they can also be arranged next to each other.

At the start of a process, substrates 43, 44, 45 are located in a feed chamber E, which is evacuated, e.g. over a period of 0.4 min. During the same time, the waiting chambers W₁, W₂ are empty, whereas in the etching chamber B₁ a substrate 46, in the coating chamber B₂ a substrate 47 and in the second coating chamber B₃ a substrate 48 are treated simultaneously. There are three substrates 49, 50, 51 in the discharge chamber, which are discharged after ventilation of the discharge chamber (see second line). At the same time as the discharge, the mentioned substrates are moved on until the state shown in the third line is reached, in which two substrates 43, 44 are treated in the waiting chamber and substrates 45, 46, 47 are treated in each of the treatment chambers B₁, B₂, B₃. The substrate 48 is arranged in the waiting chamber. The feed chamber is ventilated, while the discharge chamber is still evacuated. Now, as shown in the fourth line, the feed chamber can be loaded with new substrates 52, 53, 54. The displacement of the substrates 43, 44, 45, 46 into the respective adjacent chamber with the valves open is shown in line 4. After loading the feed chamber E, this chamber is evacuated (see fifth line), while the substrate 43 is in the waiting chamber W₁ and the substrates 44, 45, 46 are in the respective treatment chambers B₁, B₂, B₃, where they are etched or provided with the first or second coating. The substrates 47, 48 are located in the waiting chamber W₂. The discharge chamber is evacuated. After the evacuation and treatment time, the substrates 43, 44, 45, 46, 47, 48 are each conveyed further until an arrangement corresponding to the initial situation is reached, in which three substrates 52, 53, 54 are evacuated in the feed chamber, simultaneously substrates 43, 44, 45 are etched or coated in the treatment chambers B₁, B₂, B₃, and substrates 46, 47, 48 are arranged in the discharge chamber, which is already being ventilated. After the treatment and evacuation or ventilation time of 0.4 min, the process is continued as shown in the last line.

FIGS. 2 to 4 clearly show that the feed and discharge chambers can each be loaded with n=2 or n=3 substrates, whereas the waiting chambers have a loading capacity of two substrates. Only one substrate can be placed in each of the treatment chambers.

The insertion of additional waiting chambers and the increase in the capacity of the feed and discharge chambers require comparatively lower investments than the revenue generated by the increase in productivity.

1. An inline system for coating individual substrates or groups of substrates, which has several chambers arranged one behind the other and evacuatable via pumps, namely a feed chamber, a waiting chamber, at least one process chamber, a further waiting chamber and a discharge chamber, through which the substrates or substrate groups pass in succession and which can each be closed by valves, wherein
the feed chamber and the discharge chamber each have a capacity for simultaneously receiving n substrates or substrate groups arranged behind or next to one another, where n is a natural number>1, and in that the waiting chamber arranged between the feed chamber and the process chamber as well as between the discharge chamber and the process chamber has a capacity for receiving (n−1) substrates or substrate groups, whereas the capacity of the treatment chambers is limited to receiving one substrate or one substrate group in each case.

2. The inline system according to claim 1, wherein the feed and discharge chambers are n times as long as each of the treatment chambers.

3. The inline system according to claim 1, wherein an etching chamber and one, preferably two, coating chambers are provided as process chambers.

4. The inline system according to claim 1, wherein the coating chambers have a PVD device.

5. A method for coating individual substrates or substrate groups in an inline coating system according to claim 1, wherein
between respective etching and/or coating treatments, the substrates or substrate groups are moved in composite from the feed chamber via the waiting chamber into the treatment chambers and a further waiting chamber into the discharge chamber and are treated in such a way that in successive steps the feed chamber is occupied with n substrates or n substrate groups and each of the treatment chambers is occupied with only one substrate or one substrate group and the waiting chambers are free of substrates or substrate groups, the substrates or substrate groups are then moved forward to such an extent that a substrate or a substrate group discharged from each treatment chamber is replaced by a substrate or a substrate group carried forward and that, after partial occupancy of the waiting chamber, the feed chamber is occupied with n substrates or substrate groups, after which the sequence of substrate movement and chamber occupancy described above is repeated successively.

6. The method according to claim 5, wherein the substrates or substrate groups are subjected to an etching process before coating.

7. The method according to claim 5, wherein the substrates are coated in two layers.
